(19) United States
(12) Patent Application Publication
(10) Pub. No.: US 2025/0167052 A1
(43) Pub. Date: May 22, 2025

(54) POSITION RECONSTRUCTION OF SEMICONDUCTOR COMPONENTS ON A WAFER

(71) Applicant: Robert Bosch GmbH, Stuttgart (DE)

(72) Inventors: Eric Sebastian Schmidt, Heimsheim (DE); Stefan Patrick Lindt, Ettlingen (DE)

(21) Appl. No.: 18/837,621

(22) PCT Filed: Feb. 6, 2023
(86) PCT No.: PCT/EP2023/052854

§ 371 Date: Aug. 12, 2024

(30) Foreign Application Priority Data
Feb. 23, 2022 (DE) 10 2022 201 902.4

(51) Int. Cl. H01L 21/66; H01L 21/67

(52) U.S. Cl. CPC H01L 22/12; H01L 21/67259

(57) ABSTRACT

A method for ascertaining an assignment rule in order to combine test results of different tests of the same semiconductor element. The method includes the following steps: adapting a model, for example, a linear regression model, use of the model for predicting the test data, calculating a cost matrix on the basis of the predictions, applying a greedy implementation to the cost matrix in order to obtain a new assignment rule and repeating these steps multiple times.

### FIELD

The present invention relates to a method for reconstructing the positions of semiconductor components on a wafer onto which the semiconductor components were applied, after the semiconductor components have been cut out of the wafer, and to a device configured to perform the method.

### BACKGROUND INFORMATION

In the packaging process of semiconductor components (specifically PowerMOS), traceability of the semiconductor components to their original wafer and their original position on the wafer is lost. Concretely, this means that the position of each semiconductor component on a wafer is no longer available once the wafer has been cut or diced (a method in which semiconductor components are separated from the wafer) and packaged. Providers of packaging processes are able to offer at least rough matching between loose semiconductor components in the final test (test process of the semiconductor components after packaging) and semiconductor components on the wafer in wafer level tests (test process before packaging). However, this still results in several thousand semiconductor components that cannot be assigned to several wafers. Since this is essentially a combinatorial problem, the complexity of achieving this object is factorial since there are n factorial different possibilities of arranging the semiconductor components such that they correspond to the correct order, wherein n is the number of semiconductor components.

For ASIC semiconductor components, there is a solution to this combinatorial problem. For this purpose, an unambiguous identifier is stored in the memory of the ASIC semiconductor components during the wafer level test, which makes assigning the final test to the wafer level test after packaging possible. However, for semiconductor components such as PowerMOS, this is not possible due to a lack of memory.

### SUMMARY

The present invention may have the advantage that, using a greedy algorithm, a potential assignment between semiconductor components is ascertained particularly efficiently depending on the results of the wafer-level test and packaged semiconductor components and depending on the results of the final test, without subsequently added metadata, such as unique identifiers or the like. This is because the greedy algorithm results in significantly lower computing and memory complexity, which means that no expensive hardware is required and the assignment can be ascertained in a fraction of the computing time. This also allows the use of significantly larger quantities of semiconductor components, particularly without increasing the error rate. The present invention thus broadens the scope of application, as the increased computing efficiency means that more semiconductor components than before can now be assigned.

An object of the present invention is to increase the quantity of semiconductor components to be processed by at least one order of magnitude.

The present invention may also have the advantage of making possible a one-to-one assignment between semiconductor components and their original position on the wafer and thus better process control (e.g., root cause analysis of defective parts).

Further aspects and example embodiments of the present invention are disclosed herein. Advantageous developments of the present invention are disclosed herein.

In a first aspect, the present invention relates to a method, in particular a computer-implemented method, for ascertaining an assignment rule which assigns variables from a first set of first variables to respective variables from a second set of second variables. The assignment rule can assign the first variables to the second variables in an unambiguous manner, i.e., at most one second variable is assigned to each first variable by the assignment rule and preferably also vice versa. A set can be understood as a form of combining the individual variables. Preferably, the first and second sets are different sets that do not have a common variable. Preferably, an index is assigned to each of the variables of the first and second sets. All indices of the first and second sets could be regarded as index sets. That is to say, as a set whose elements index the variables of the first or second set. The assignment rule then assigns an index from the second index set to each element of the first index set. The assignment rule accordingly describes which first variable is associated with which second variable and preferably also vice versa. The assignment rule can be in the form of a list or table or the like.

According to an example embodiment of the present invention, the method begins with initializing the assignment rule and providing the first and second sets. The initial assignment rule can be selected randomly or as an identity assignment. Other initial assignment rules are possible as an alternative, e.g. a predefined, already partially correct assignment.

This is followed by repeated performance of steps a) through d) described below. The repetitions can be carried out for a predefined number of maximum repetitions or a termination criterion can be defined, wherein the repetition is terminated if the termination criterion is met. The termination criterion is, for example, a minimum change to the assignment rule.
a) Creating a data set which contains the first variables and their respective second variables assigned according to the assignment rule. The data set can also be referred to as a training data set, wherein the assigned second variables are so-called “labels” of the first variables. It should be noted that this step can be optional, since the subsequent steps using this data set essentially require only the information of the current assignment rule between the first and second variables, which can be provided either by the data set or by a current assignment rule. The current assignment rule is the assignment rule that exists for the current repetition of steps a) through d), i.e. the assignment rule that was used when the most recent creation of the data set was performed.
b) Training a machine learning system such that the machine learning system ascertains the respectively assigned second variables of the data set depending on the first variables. Training can be understood to mean that parameters of the machine learning system are adjusted so that the predictions ascertained by the machine learning system are as close as possible to the second variables (“labels”) of the data set. The optimization can be carried out with regard to a cost function. The cost function preferably characterizes a mathematical difference between the outputs of the machine learning system and the labels. The optimization is preferably carried out using a gradient descent method. The machine learning system may be one or a plurality of decision trees, a neural network, a support vector machine, or the like. Training can be carried out until a further improvement in the machine learning system during training is negligible, i.e. a second termination criterion is met.
c) Ascertaining a set of distances between predictions of the machine learning system and the second variables. The distances can be calculated successively, wherein each distance between the prediction of the machine learning system and the second variables is characterized according to the assignment rule, in particular between each variable of the second set to all predictions of the machine learning system. Preferably, the distances are ascertained in the form of a cost matrix, wherein entries of the cost matrix characterize a distance between the prediction of the machine learning system and the second variables according to the assignment rule, in particular between the predictions of the machine learning system and all variables of the second set. The distance can be ascertained using an L₂ norm. Other spacing measures are also possible. The cost matrix can be structured such that rows and columns are each assigned to a first variable or the prediction of the machine learning system depending on the first variable and a second variable, wherein the entries characterize the distance between the respective assigned variables of the rows and columns. The entries that do not lie on the diagonal of the cost matrix can be regarded as transportation costs that must be incurred in order to assign the first variables to the respective second variables of the corresponding rows/columns counter to the assignment rule.
d) Optimizing the assignment rule depending on the cost matrix in order for the assignment rule to generate minimal total costs, in particular a minimum total distance, based on the entries of the cost matrix. Total costs correspond to a sum of those entries of the cost matrix that are required from the cost matrix when performing an assignment of the variables of the first set to the second set according to the current assignment rule. In other words, the sum is optimized, in particular minimized, over the entries that are selected from the cost matrix depending on the assignment rule. It should be noted that the entries are selected depending on the assignment rule such that the entries of the respective column and row of the cost matrix are selected according to the assignment rule, which are assigned to the first and second variables that are assigned to each other according to the assignment rule.

According to an example embodiment of the present invention, the assignment rule is optimized by the following steps, which are repeated iteratively in particular until a termination criterion is met. The termination criterion can be defined, for example, by the fact that the following steps have been carried out for all predictions of the machine learning system:
i) randomly drawing a prediction of the machine learning system and selecting the second variable which, according to the cost matrix, has the smallest distance to the drawn prediction of the machine learning system. In other words, the cost matrix is used to select the second variable, the entry of which in the cost matrix characterizes the smallest distance to the said prediction.
ii) modifying the assignment rule such that the assignment rule assigns the selected second variable to the first variable depending on which the drawn prediction of the machine learning system was ascertained; and
iii) removing the entries assigned to the first variable, depending on which the machine learning system's drawn prediction was ascertained, and the entries assigned to the selected second variable from the cost matrix.

In each iteration for the optimization of the assignment rule, the above method selects the smallest distance between a prediction of the machine learning system and the second variables. Since the method only considers a single target observation, the problem is optimized locally or greedily. It is therefore safe to say that this is a greedy implementation. Removing the selected variables after modifying the assignment rule has the advantageous effect that a one-to-one assignment can be enforced.

This provided manner does not minimize the costs globally, but locally, but it is considerably more computationally efficient and it has been found that, surprisingly, it does not degrade the quality of the assignment rule, as the greedy implementation leads to similar results. Presumably, this is due to the fact that the greedy implementation ascertains the assignment rule independently of all other entries in the cost matrix, wherein the row indices of the column minima of the cost matrix are more or less unambiguous.

The assignment rule ascertained in the last repetition of step d) is the final assignment rule, which is output in an optional step.

The variables can be scalars or vectors such as a time series, in particular sensor data recorded by a sensor or indirectly ascertained. Preferably, the first and second variables are respectively one or a plurality of measurement results from a measurement or from a plurality of different measurements, which were respectively carried out on an object of a plurality of objects. This means that each variable is assigned to one of the objects. In the step of creating the data set, only a predeterminable number of measurement results of the plurality of measurement results can be used for the second variables. The assignment rule can specify which first and second variables are measurement results of the same object. Particularly preferably, the at least one measurement of the objects for the first variables was performed at a first time and the measurement for the second variables was carried out at a second time, wherein the second time is after the first time. The second time may, for example, be after the objects have been subjected to a modification or change.

According to an example embodiment of the present invention, it is provided that a batch-size is specified, wherein a plurality of randomly selected predictions of the machine learning system is selected when ascertaining the cost matrix, wherein the plurality of randomly selected predictions of the machine learning system corresponds to the batch-size, wherein, furthermore, when ascertaining the cost matrix, the distances between the plurality of the randomly drawn predictions of the machine learning system to the second variables are ascertained. The advantage is that the complexity is significantly reduced (compared to the previous implementation of the Hungarian algorithm). Previously the complexity was O(n³), now it is O(n*batch size³)=O(n).

According to an example embodiment of the present invention, it is further provided that when optimizing the assignment rule based on the entries of the cost matrix, a selection is made depending on a set bit flag as to whether the assignment rule is optimized using steps i) to iii) or using a Hungarian algorithm. The advantage in this is that the optimization can be changed flexibly, for example if the Hungarian algorithm got stuck in a local minimum and the bit flag thereupon was set accordingly.

The Hungarian method, also known as the Kuhn-Munkres algorithm, is an algorithm for solving weighted assignment problems.

Furthermore, according to an example embodiment of the present invention, it is provided that the machine learning system is a regression model which ascertains the second variables depending on the first variables and parameters of the regression model, wherein the parameters of the regression model are adjusted during the training.

The regression is used to model relationships between a dependent (often also response variable) and one or more independent variables (often also explanatory variables). The regression is able to parameterize a more complex function so that this function best represents data according to a particular mathematical criterion. For example, the common method of least squares calculates an unambiguous straight line (or hyperplane) that minimizes the sum of squares of the deviations between the true data and this line (or hyperplane), i.e., the residual sum of squares.

According to an example embodiment of the present invention, preferably, the regression model is a linear regression model, wherein a Tikhonov regularization is used during training.

Linear regression aims to minimize the quadratic regression loss, which is why the squared Euclidean distance is preferably selected as the distance measure for the cost matrix.

Furthermore, according to an example embodiment of the present invention, it is provided that the first and second variables characterize a product during the production thereof after different production process steps. For example, the second time may be when a production process step has been completed. The product may be any product produced in a manufacturing plant. Preferably, when the product is produced, the traceability to its previous process steps is lost (so-called “bulk material”), for example if it is no longer possible to directly assign the product from the bulk material, e.g., screws, to a production batch. It is possible that the first variables characterize components, in particular component parts, and the second variables characterize final products, wherein the assignment rule describes which component has been processed into which product or which component part has been installed in which product. For example, if the component part in the product can no longer be removed in a non-destructive manner in order to read a serial number. With the present invention, it is then possible to assign the production batch of the component part on the basis of measurements of the product.

The first and second variables may be measurement/test results or other properties of the products, components, etc. The first and second variables preferably differ slightly from one another, e.g., due to manufacturing tolerances, but describe the same measurements/properties of the products, components, etc.

According to an example embodiment of the present invention, it is furthermore provided that the first variables are first test results or measurement results of semiconductor component elements on a wafer and the second variables are second test results or measurement results of the semiconductor component elements after the semiconductor component elements have been cut out of the wafer. Semiconductor component elements may be parts of grown electrical component parts on the wafer, e.g., a transistor group of an integrated circuit. The test results may also refer to the entire semiconductor component. Here, linear regression has proven to be particularly effective for the machine learning system in finding the best assignment rule. This is because linear regression is based on a linear correlation, which is a reasonable assumption for the assignment of test results here. Linear regression is a special case of regression. In linear regression, a linear function is assumed. That is to say, only correlations in which the dependent variable is a linear combination of the regression coefficients (but not necessarily of the independent variables) are used.

Furthermore, according to an example embodiment of the present invention, it is provided that the first test results are wafer level test results and the second test results are final test results. Preferably, there are fewer final test results than wafer level test results. The tests are, for example, voltage tests and/or contact tests.

Furthermore, according to an example embodiment of the present invention, it is provided that the semiconductor component elements have been produced on a plurality of different wafers. This is because it has been found that the method is even capable of finding a correct assignment rule across multiple wafers within a reasonable computing time.

According to an example embodiment of the present invention, it is furthermore provided that it is ascertained, depending on the assignment rule, which second test result is associated with which first test result, and wherein it is then ascertained, depending on the associated first test result, at which position the semiconductor component was arranged within a wafer. This allows a position reconstruction, which makes it possible for the first time to unambiguously trace the semiconductor components from the final production process steps of the semiconductor production to previous process steps.

According to an example embodiment of the present invention, it is furthermore provided that, in addition to the positions, further variables characterizing the wafer and/or the semiconductor components on the wafer are ascertained along with respectively assigned test results, wherein these data are combined into a further training data set, wherein, depending on the further training data set, a further machine learning system is trained to predict the second test results.

An advantage here is that the assignment can be used to create a further training data set in order to train a further machine learning system to predict properties of a packaged semiconductor element at an early stage of the production process. This significantly reduces the time until deviations in the process parameters are detected. In particular for parameters that can only be correctly evaluated during final tests (e.g., RDSon).

A further advantage here is that the assignment can also be used to train a further machine learning system that actively identifies defective semiconductor chips. This saves process resources and reduces waste.

In further aspects, the present invention relates to a device and to a computer program, which are each configured to perform the above methods of the present invention, and to a machine-readable storage medium in which this computer program is stored.

Example embodiments of the present invention are explained in greater detail below with reference to the figures.

### BRIEF DESCRIPTION OF THE DRAWINGS

FIG. 1 schematically shows a packaging process.

FIG. 2 schematically shows an embodiment example of a flowchart of the present invention.

FIG. 3 schematically shows a training device, according to an example embodiment of the present invention.

### DETAILED DESCRIPTION OF EXAMPLE EMBODIMENTS

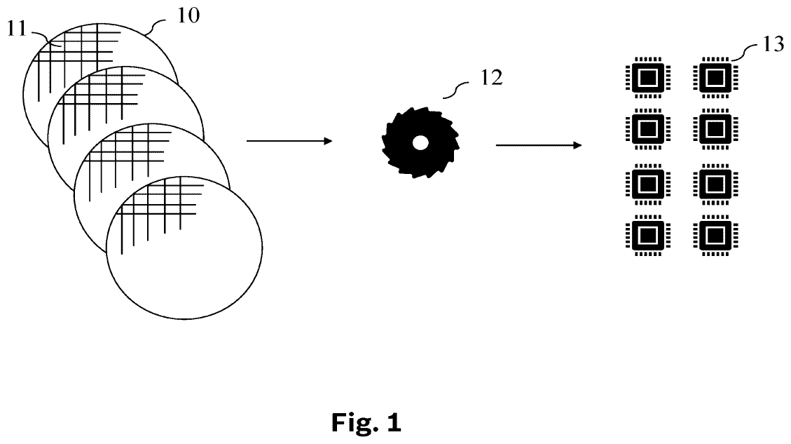

In the packaging process of semiconductor components or semiconductor elements, the traceability of the elements to their original wafer and their original position on the respective wafer is usually lost. This is because, after cutting out the semiconductor elements, mixing of the individual semiconductor elements may occur, whereby the position of the component parts on the wafer is lost if they do not have an unambiguous marking. This is schematically shown in FIG. 1. The wafers 10 respectively have a plurality of semiconductor components or semiconductor elements 11. At this stage, each semiconductor element 11 has a known position on the wafers 10. At this stage, the semiconductor elements 11 are usually subjected to a plurality of tests, which are also referred to as the wafer level test. This is followed by cutting the wafers 10 so that the semiconductor elements 11 are separated from one another. Cutting may take place by means of a saw 12 or by means of a laser. Finally, the cut semiconductor elements are packaged, for example installed in microcontrollers 13. No later than at this stage is the information lost as to the wafer 10 and the position within the wafer 10 at which the semiconductor element was originally positioned. Usually, the microcontrollers 13 with the semiconductor elements 11 are again subjected to a plurality of tests, which are also referred to as the final test. However, since mixing took place as a result of cutting the wafers 10, it cannot be readily unambiguously traced on which wafer 10 the respective semiconductor element 11 of the microcontrollers 13 was arranged and which wafer level test corresponds to which final test, i.e., are the test results of the same semiconductor element. The semiconductor elements may be microelectronic assemblies, such as integrated circuits (hereinafter also referred to as a chip), sensors, or the like.

One object of the present invention is to restore traceability after the packaging process in a semiconductor manufacturing process. Such an assignment makes further contributions, such as better process control or early prediction of final chip properties, possible. Moreover, the cause analysis of the deviations measured in the final test at the chip level can be expanded to the processes in the wafer production. This in turn makes possible a much deeper understanding of the processes and leads to better process control and thus better quality.

The present invention proposes an assignment algorithm that consists of an alternating sequence of optimizing regression parameters (when regressing from wafer-level test to final test data) and subsequently optimizing the assignment of test partners. The current assignment of the final test chips is used as a regression label in each iteration.

The present invention also uses a cost-minimizing algorithm that can ascertain an optimal one-to-one assignment under a predefined cost matrix. In order to construct a suitable cost matrix, a regression error is used by calculating a suitable distance measure (e.g. L₂ norm) between the final test prediction of a trained regressor and the regression label. Based on this cost matrix, the algorithm rearranges the chips in the final test such that the regression loss is minimized. Depending on the characteristics of the data, the regressor or regression model can be freely selected (e.g. linear regression for linear dependencies).

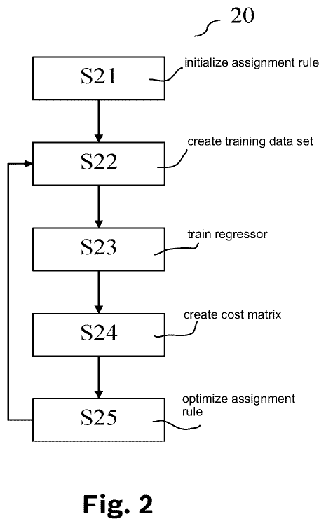

FIG. 2 schematically illustrates a flowchart 20 of a method for ascertaining an assignment rule that assigns the test results of the final test to the corresponding wafer-level test results. After the method has been completed, there should be an assignment rule, which assigns the associated test results of the wafer level test to the final tests. In other words, it describes test results that belong together and originate from the same semiconductor component.

The method starts with step S21. The assignment rule is initialized in this step. The test results of the wafer level test (WLT) and final tests (FT) are also provided in this step.

This is followed by step S22, in which a training data set is created that contains the WLT test results and their respective FT test results assigned according to the assignment rule.

After step S22 has been completed, step S23 follows. In this step, a regressor f is trained to ascertain the assigned final tests depending on the wafer level tests (WLT) according to the training data set: f(WLT)=FT. The regressor f can be a linear regression model. The regressor is trained in a conventional manner, e.g., by minimizing a regression error on the training data set by adapting parameters of the regressor f.

After the regressor has been trained, step S24 follows. A cost matrix is created here. The rows and columns are each assigned to a wafer-level test and final test. The entries of the cost matrix are ascertained from the training data, for example, by means of a L₂ norm between the prediction of the regressor depending on the corresponding WFT test result of the respective row and the corresponding FT test result of the respective column, and are stored in the cost matrix.

After step S24 has been completed, the assignment rule is optimized in step S25. The optimization is performed using the greedy implementation explained above and/or by applying the Hungarian algorithm to the cost matrix in order to obtain an improved assignment rule based on the cost matrix.

If a termination criterion is not met, steps S22 to S25 are carried out again. The termination criterion can be a predefined maximum number of repetitions.

If the termination criterion is met, the method is ended and the assignment rule can be output.

In a step optionally following step S25, the position of the semiconductor components 11 on the wafer 10 is reconstructed by means of the assignment rule. The assignment rule can be used to determine the WLT test results backwards, starting with the FT test results. Since the position within the wafer at which the respective test has been carried out is usually stored in addition to the WLT test results, it can thus be reconstructed where exactly the corresponding semiconductor element was produced on the wafer.

It is possible that, depending on a position reconstruction after step S25, a control signal for controlling a physical system, such as a computer-controlled machine, such as a production machine, in particular processing machines for the wafers, is activated. For example, if the FT test results are not optimal, the control signal can adapt a previous production step accordingly in order to obtain better FT test results later.

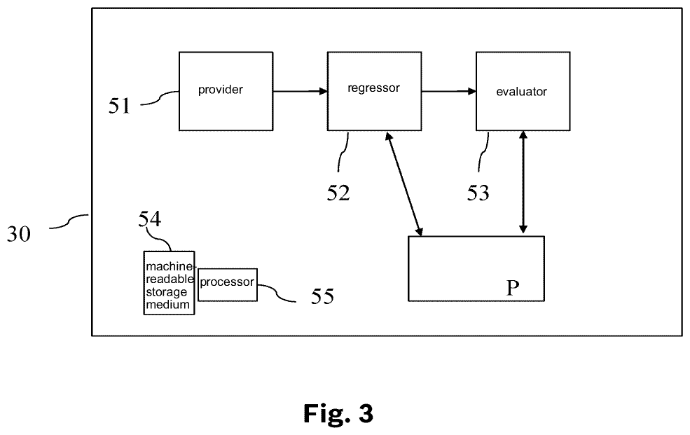

FIG. 3 schematically shows an apparatus 30 for carrying out the method according to FIG. 2.

The apparatus comprises a provider 51 that provides the training data set according to step S22. The training data are then fed to the regressor 52, which uses the training data to ascertain output variables. Output variables and training data are supplied to an evaluator 53, which ascertains updated parameters of the regressor 52, which are transmitted to the parameter memory P and replace the current parameters there. The evaluator 53 is configured to carry out step S23.

The steps carried out by the device 30 may be implemented as a computer program stored on a machine-readable storage medium 54 and carried out by a processor 55.

The term “computer” comprises any device for processing predeterminable calculation rules. These calculation rules May be present in the form of software, in the form of hardware or also in a mixed form of software and hardware.

1-13. (canceled)

14. A method for ascertaining an assignment rule that assigns first variables from a first set of first variables to second variables from a second set of second variables, comprising the following steps:
initializing the assignment rule and providing the first and second set; and
repeatedly executing the following steps a) through c):
a) training a machine learning system such that the machine learning system, as a function of the first variables, ascertains the second variables assigned in each case in accordance with the assignment rule,
b) ascertaining a set of distances between predictions of the machine learning system depending on the first variables and the second variables, and
c) optimizing the assignment rule depending on the set of ascertained distances, so that an assignment of the first variables to the second variables according to the assignment rule generates a minimum total distance depending on the ascertained distances, wherein the following steps are carried out multiple times consecutively for the optimizing of the assignment rule:
i) randomly drawing a prediction of the machine learning system and selecting the second variable which has the smallest ascertained distance to the drawn prediction of the machine learning system,
ii) modifying the assignment rule such that the assignment rule assigns the selected second variable to the first variable depending on which the drawn prediction of the machine learning system was ascertained, and
iii) removing the distances from the set of ascertained distances, which were respectively ascertained based on the first variable, depending on which the drawn prediction of the machine learning system was ascertained, and which were respectively ascertained based on the selected second variable.

15. The method according to claim 14, wherein a batch size is specified, wherein when ascertaining the set of distances, a plurality of randomly selected predictions of the machine learning system is selected, wherein a number of the plurality of randomly selected predictions of the machine learning system corresponds to the batch-size, wherein also when ascertaining the set of distances, distances between the plurality of randomly drawn predictions of the machine learning system to the second variables are ascertained.

16. The method according to claim 14, wherein when optimizing the assignment rule, it is selected depending on a set bit flag whether the optimization of the assignment rule is carried out using steps i) to iii) or using a Hungarian algorithm.

17. The method according to claim 14, wherein the machine learning system is a regression model which ascertains the second variables depending on the first variables and parameters of the regression model.

18. The method according to claim 17, wherein the regression model is a linear regression model, and wherein a Tikhonov regularization is used in the training.

19. The method according to claim 14, wherein the first and second variables characterize products during production of the products after different production process steps, wherein the assignment rule characterizes which of the variables of the first and second sets characterize a same product.

20. The method according to claim 19, wherein the first variables are first test results of semiconductor component elements on a wafer and the second variables are second test results of semiconductor component elements after they have been cut out of the wafer, wherein the assignment rule characterizes which first and second test results are from the same semiconductor component element, wherein the first test results are wafer-level test results and the second test results are final test results.

21. The method according to claim 20, wherein the semiconductor component elements are produced on a plurality of different wafers, and wherein the semiconductor component elements are power MOSFETs.

22. The method according to claim 20, wherein it is ascertained, depending on the assignment rule, which second test result is associated with which first test result, and wherein it is then ascertained, depending on the associated first test result, at which position the semiconductor element was arranged within the wafer.

23. The method according to claim 22, wherein, further variables characterizing the wafer and/or the semiconductor component elements on the wafer and respectively assigned second test results are ascertained, wherein the further variables are combined to form a training data set, wherein, depending on the training data set, a further machine learning system is trained in order to predict the second test results.

24. A device configured to ascertain an assignment rule that assigns first variables from a first set of first variables to second variables from a second set of second variables, the device configured to:
initialize the assignment rule and providing the first and second set; and
repeatedly execute the following steps a) through c):
a) training a machine learning system such that the machine learning system, as a function of the first variables, ascertains the second variables assigned in each case in accordance with the assignment rule,
b) ascertaining a set of distances between predictions of the machine learning system depending on the first variables and the second variables, and
c) optimizing the assignment rule depending on the set of ascertained distances, so that an assignment of the first variables to the second variables according to the assignment rule generates a minimum total distance depending on the ascertained distances, wherein the following steps are carried out multiple times consecutively for the optimizing of the assignment rule:
i) randomly drawing a prediction of the machine learning system and selecting the second variable which has the smallest ascertained distance to the drawn prediction of the machine learning system,
ii) modifying the assignment rule such that the assignment rule assigns the selected second variable to the first variable depending on which the drawn prediction of the machine learning system was ascertained, and
iii) removing the distances from the set of ascertained distances, which were respectively ascertained based on the first variable, depending on which the drawn prediction of the machine learning system was ascertained, and which were respectively ascertained based on the selected second variable.

25. A non-transitory machine-readable storage medium on which is stored a computer program for ascertaining an assignment rule that assigns first variables from a first set of first variables to second variables from a second set of second variables, the computer program, when executed by a computer, causing the computer to perform the following steps:
initializing the assignment rule and providing the first and second set; and
repeatedly executing the following steps a) through c):
a) training a machine learning system such that the machine learning system, as a function of the first variables, ascertains the second variables assigned in each case in accordance with the assignment rule,
b) ascertaining a set of distances between predictions of the machine learning system depending on the first variables and the second variables, and
c) optimizing the assignment rule depending on the set of ascertained distances, so that an assignment of the first variables to the second variables according to the assignment rule generates a minimum total distance depending on the ascertained distances, wherein the following steps are carried out multiple times consecutively for the optimizing of the assignment rule:
i) randomly drawing a prediction of the machine learning system and selecting the second variable which has the smallest ascertained distance to the drawn prediction of the machine learning system,
ii) modifying the assignment rule such that the assignment rule assigns the selected second variable to the first variable depending on which the drawn prediction of the machine learning system was ascertained, and
iii) removing the distances from the set of ascertained distances, which were respectively ascertained based on the first variable, depending on which the drawn prediction of the machine learning system was ascertained, and which were respectively ascertained based on the selected second variable.
